(19) United States
(12) Patent Application Publication
(10) Pub. No.: US 2023/0245882 A1
(43) Pub. Date: Aug. 3, 2023

(54) DEPOSITION METHOD AND DEPOSITION APPARATUS

(71) Applicant: Tokyo Electron Limited, Tokyo (JP)

(72) Inventors: Yosuke WATANABE, Yamanashi (JP); Ryoun SHIMAMOTO, Yamanashi (JP); Shota CHIDA, Hillsboro, OR (US)

(21) Appl. No.: 18/161,298

(22) Filed: Jan. 30, 2023

(30) Foreign Application Priority Data
Feb. 3, 2022 (JP) 2022-015860

(51) Int. Cl. H01L 21/02; H01L 21/67; C23C 28/04

(52) U.S. Cl. CPC H01L 21/02271; H01L 21/02115; H01L 21/67098; H01L 21/02205; C23C 28/04; H01L 21/02304

(57) ABSTRACT

A deposition method includes: forming a seed layer on a substrate; and forming a carbon film on the seed layer. The forming the seed layer includes: supplying an aminosilane-based gas to the substrate to form a Si—H bond on a surface of the substrate; and supplying a boron-containing gas to the substrate to form a B—H bond on the surface on which the Si—H bond is formed.

### CROSS-REFERENCE TO RELATED APPLICATIONS

The present application is based on and claims priority to Japanese Patent Application No. 2022-015860 filed on Feb. 3, 2022, the contents of which are incorporated herein by reference in their entirety.

### BACKGROUND OF THE INVENTION

### Field of the Invention

The present disclosure relates to a deposition method and a deposition apparatus.

### Description of the Related Art

A technique is known in which a hydrocarbon-based carbon source gas and a halogen element-containing thermal decomposition temperature drop gas are introduced into a processing chamber, and a carbon film is deposited at a low temperature using thermal chemical vapor deposition (CVD) (see, for example, Japanese Laid-Open Patent Publication No. 2014-033186 and Japanese Laid-Open Patent Publication No. 2017-210640).

### SUMMARY OF THE INVENTION

According to one aspect of the present disclosure, a deposition method includes: forming a seed layer on a substrate; and forming a carbon film on the seed layer, wherein the forming the seed layer includes: supplying an aminosilane-based gas to the substrate to form a Si—H bond on a surface of the substrate; and supplying a boron-containing gas to the substrate to form a B—H bond on the surface on which the Si—H bond is formed.

### BRIEF DESCRIPTION OF THE DRAWINGS

FIG. 1 is a schematic cross-sectional view illustrating a deposition apparatus according to an embodiment;

FIG. 2 is a flowchart illustrating a deposition method for a carbon film according to an embodiment;

FIGS. 3A to 3C are cross-sectional views illustrating steps of forming a seed layer according to an embodiment;

FIGS. 4A and 4B are cross-sectional views illustrating steps of forming a carbon film according to an embodiment;

FIG. 5 is a diagram illustrating the evaluation results of underlayer damage and adhesion; and

FIG. 6 is a diagram illustrating the measurement results of the XPS spectrum of the carbon film.

### DESCRIPTION OF THE EMBODIMENTS

Hereinafter, non-limiting exemplary embodiments of the present disclosure will be described with reference to the accompanying drawings. In all the accompanying drawings, the same or corresponding members or parts are denoted by the same or corresponding reference numerals, and overlapping descriptions are omitted.

### [Seed Layer When Depositing Carbon Film on Underlayer]

By using a carbon-containing gas added with a thermal decomposition temperature drop gas, a carbon film can be deposited at a low temperature (for example, 390° C. to 450° C.) on an underlayer. In this case, in order to deposit a carbon film having excellent adhesion to the underlayer while preventing damage to the underlayer, a boron nitride (BN) film is formed on the underlayer, and then the carbon film is deposited.

The BN film has high etching resistance, but is difficult to remove. Therefore, there is a need for a technique capable of suppressing underlayer damage and forming a carbon film having excellent adhesion without using a BN film.

Hereinafter, an example of a deposition apparatus and a deposition method for forming a carbon film having excellent adhesion and capable of preventing underlayer damage will be described.

### [Deposition Apparatus]

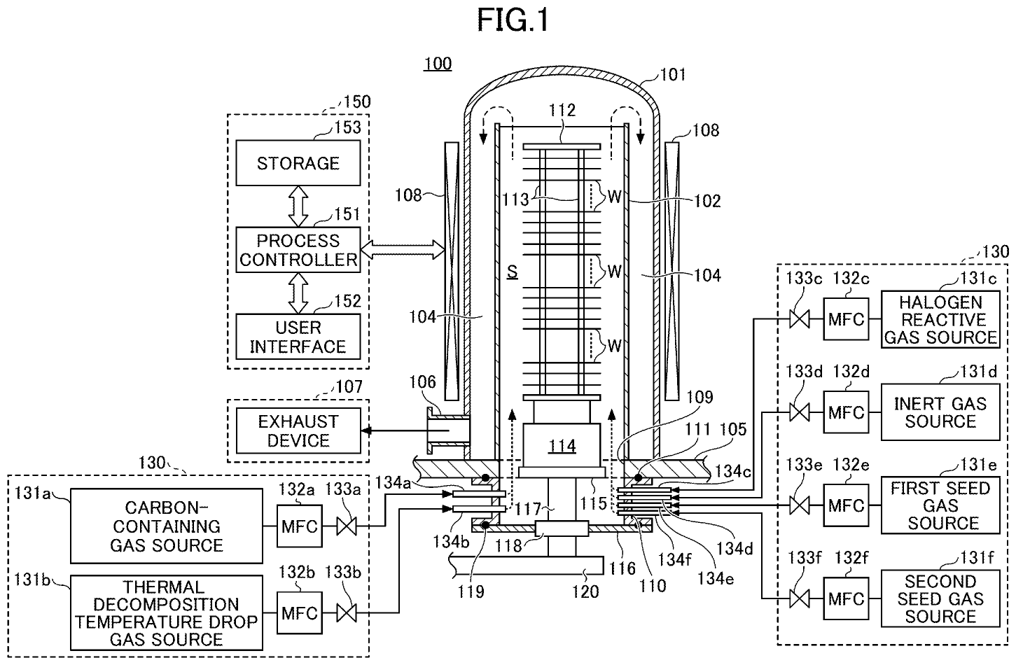

Referring to FIG. 1, a deposition apparatus according to an embodiment will be described. As illustrated in FIG. 1, a deposition apparatus 100 is configured as a vertical batch-type deposition apparatus, and includes a cylindrical outer wall 101 with a ceiling and a cylindrical inner wall 102 provided inside the outer wall 101. The outer wall 101 and the inner wall 102 are made of, for example, quartz, and the inner region of the inner wall 102 serves as a processing chamber S in which a plurality of substrates W are collectively processed. The substrate W is, for example, a semiconductor wafer.

The outer wall 101 and the inner wall 102 are separated from each other in the horizontal direction with an annular space 104 interposed therebetween, and are joined to the base material 105 at their lower ends. The upper end of the inner wall 102 is separated from the ceiling of the outer wall 101 so that the top of the processing chamber S is communicated with an annular space 104. The annular space 104 communicating with the top of the processing chamber S serves as an exhaust flow path. The gas supplied to and diffused into the processing chamber S flows from the bottom of the processing chamber S to the top of the processing chamber S and is drawn into the annular space 104. An exhaust pipe 106 is connected to, for example, the lower end of the annular space 104, and the exhaust pipe 106 is connected to an exhaust device 107. The exhaust device 107 includes a vacuum pump, an exhaust valve, and the like, evacuates the processing chamber S, and adjusts the internal pressure of the processing chamber S to an appropriate pressure for processing.

A heater 108 is provided outside the outer wall 101 so as to surround the processing chamber S. The heater 108 adjusts the temperature inside the processing chamber S to a temperature suitable for processing, and heats a plurality of substrates W collectively.

The bottom of the processing chamber S communicates with an opening 109 provided in the base material 105. A cylindrical manifold 110 made of, for example, stainless steel is connected to the opening 109 via a sealing member 111 such as an O-ring. The bottom of the manifold 110 is an opening through which a boat 112 is inserted into the processing chamber S. The boat 112 is made of, for example, quartz and includes a plurality of pillars 113. Grooves (not illustrated) are formed in each of the pillars 113. The grooves support a number of substrates that are processed simultaneously. Accordingly, in the boat 112, a plurality of (for example, 50 to 150) substrates W can be mounted in multiple stages. By inserting the boat 112 on which the plurality of substrates W are mounted into the processing chamber S, the substrates W are accommodated within the processing chamber S.

The boat 112 is mounted on a table 115 via a thermal insulation cylinder 114 made of quartz. The table 115 is supported on a rotating shaft 117 that passes through a lid 116. The lid 116 opens and closes the opening at the bottom of the manifold 110. The lid 116 is formed of, for example, stainless steel. A magnetic fluid seal 118, for example, is provided in the penetrating portion of the lid 116 to hermetically seal and rotatably support the rotating shaft 117. A seal member 119 made of, for example, an O-ring is interposed between the periphery of the lid 116 and the lower end of the manifold 110 to keep the inside of the processing chamber S sealed. The rotating shaft 117 is attached, for example, to the end of an arm 120 supported by a lifting mechanism (not illustrated) such as a boat elevator. Accordingly, the boat 112, the lid 116, and the like are integrally elevated and lowered in a vertical direction, and inserted to and removed from the processing chamber S.

The deposition apparatus 100 includes a gas supply 130 that supplies a process gas into the processing chamber S. The gas supply 130 includes a carbon-containing gas source 131a, a thermal decomposition temperature drop gas source 131b, a halogen reactive gas source 131c, an inert gas source 131d, a first seed gas source 131e, and a second seed gas source 131f.

The carbon-containing gas source 131a is connected to a gas supply port 134a via a flow controller (MFC) 132a and an open/close valve 133a. The gas supply port 134a is provided so as to penetrate the side wall of the manifold 110 in the horizontal direction, and diffuses the supplied gas toward the interior of the processing chamber S above the manifold 110.

The carbon-containing gas supplied from the carbon-containing gas source 131a is a gas for depositing a carbon film by a low pressure chemical vapor deposition (CVD). As the carbon-containing gas, various gases can be used as long as carbon is contained. For example, hydrocarbon-based carbon source gas may be used.

Examples of the hydrocarbon-based carbon source gas include gases containing hydrocarbons represented by at least one molecular formula of CₙH₂ₙ₊₂, CₘH₂ₘ, and CₘH₂ₘ₋₂. In the formula, n is a natural number of 1 or more and m is a natural number of 2 or more.

As the hydrocarbon-based carbon source gas, benzene gas (C₆H₆) may be included.

Examples of the hydrocarbons represented by the molecular formula of CₙH₂ₙ₊₂ include methane gas (CH₄), ethane gas (C₂H₆), propane gas (C₃H₈), butane gas (C₄H₁₀; including other isomers), pentane gas (C₅H₁₂; including other isomers), and the like.

Examples of the hydrocarbons represented by the molecular formula of CₘH₂ₘ include ethylene gas (C₂H₄), propylene gas (C₃H₆; including other isomers), butylene gas (C₄H₈; including other isomers), pentene gas (C₅H₁₀; including other isomers), and the like.

Examples of the hydrocarbons represented by the molecular formula of CₘH₂ₘ₋₂ include acetylene gas (C₂H₂), propyne gas (C₃H₄; including other isomers), butadiene gas (C₄H₆; including other isomers), isoprene gas (C₅H₈; including other isomers), and the like.

The thermal decomposition temperature drop gas source 131b is connected to a gas supply port 134b via a flow controller (MFC) 132b and an open/close valve 133b. The gas supply port 134b is provided so as to penetrate the side wall of the manifold 110 in the horizontal direction, and diffuses the supplied gas toward the interior of the processing chamber S above the manifold 110.

As the thermal decomposition temperature drop gas supplied from the thermal decomposition temperature drop gas source 131b, a halogen element-containing gas is used. The halogen element-containing gas has a function of lowering the thermal decomposition temperature of the hydrocarbon-based carbon source gas by its catalytic function, thereby lowering the deposition temperature of carbon films by the thermal CVD method.

The halogen elements include fluorine (F), chlorine (Cl), bromine (Br), and iodine (I). The halogen element-containing gas may be a gas of a single halogen element, that is, a gas of fluorine (F₂) only, a gas of chlorine (Cl₂) only, a gas of bromine (Br₂) only, and a gas of iodine (I₂) only, or may be a compound containing these. The gas of a single halogen element does not require heat for thermal decomposition, and has the advantage of being highly effective in lowering the thermal decomposition temperature of the hydrocarbon-based carbon source gas. Among the above-described halogen elements, fluorine is highly reactive and may impair the surface roughness and flatness of the deposited carbon film. For this reason, chlorine, bromine, and iodine, excluding fluorine, are preferred as the halogen element. Among these, chlorine is preferable from the viewpoint of handleability.

The halogen reactive gas source 131c is connected to the gas supply port 134c via a flow controller (MFC) 132c and an open/close valve 133c. The gas supply port 134c is provided so as to penetrate the side wall of the manifold 110 in the horizontal direction, and diffuses the supplied gas toward the interior of the processing chamber S above the manifold 110.

The gas supplied from the halogen reactive gas source 131c is a gas of an element that reacts with the halogen, and includes NH₃, H₂, N₂, and the like. That is, these gases have the property of reacting with the halogen to vaporize the halogen. These gases can react with the halogen on the surface of the carbon film or in the film and remove the halogen. Among these, the gas most reactive with halogen in the low temperature CVD process is NH₃, and it is preferable to use NH₃ as the halogen reactive gas. The halogen reactive gas is not limited to ammonia, for example, H₂ and/or N₂ may be used for higher temperature processes.

The inert gas source 131d is connected to the gas supply port 134d via a flow controller (MFC) 132d and an open/close valve 133d. The gas supply port 134d is provided so as to penetrate the side wall of the manifold 110 in the horizontal direction, and diffuses the supplied gas toward the interior of the processing chamber S above the manifold 110.

The inert gas supplied from the inert gas source 131d is used as a purge gas or a dilution gas. For example, a rare gas such as N₂ gas, Ar gas, and the like may be used as the inert gas.

The first seed gas source 131e is connected to the gas supply port 134e via a flow controller (MFC) 132e and an open/close valve 133e. The gas supply port 134e is provided so as to penetrate the side wall of the manifold 110 in the horizontal direction, and diffuses the supplied gas toward the interior of the processing chamber S above the manifold 110.

A first seed gas supplied from the first seed gas source 131e is used to form a first seed layer on the underlayer, prior to forming the carbon film. The first seed layer is a layer for facilitating the formation of a second seed layer on the underlayer. As the first seed layer, a film that forms a Si—H bond on the surface of the substrate W and forms a Si—H terminated surface is used.

As the first seed gas, an aminosilane-based gas is used. Examples of the aminosilane-based gas used as the first seed gas include the gas containing at least one of butylaminosilane (BAS), bis(tert-butylamino)silane (BTBAS), dimethylaminosilane (DMAS), bis-dimethylaminosilane (BDMAS), tris-dimethylaminosilane (TDMAS), diethylaminosilane (DEAS), bis-diethylaminosilane (BDEAS), dipropylaminosilane (DPAS), and diisopropylaminosilane (DIPAS). Among these, DIPAS is preferred.

The second seed gas source 131f is connected to the gas supply port 134f via a flow controller (MFC) 132f and an open/close valve 133f. The gas supply port 134f is provided so as to penetrate the side wall of the manifold 110 in the horizontal direction, and diffuses the supplied gas toward the interior of the processing chamber S above the manifold 110.

A second seed gas supplied from the second seed gas source 131f is used to form the second seed layer on the first seed layer, prior to forming the carbon film. The second seed layer is a layer for improving the adhesion between the underlayer and the carbon film and for preventing underlayer damage when the carbon film is deposited. As the second seed layer, a film that forms a B—H bond on the surface of the substrate W and forms a B—H terminated surface is used.

As the second seed gas, a boron-containing gas is used. Examples of the boron-containing gas used as the second seed gas include a borane-based gas such as diborane (B₂H₆) gas, and boron trichloride (BCl₃) gas. Among these, B₂H₆ gas is preferred.

The deposition apparatus 100 includes a controller 150. The controller 150 includes, for example, a process controller 151 consisting of a microprocessor (computer). The process controller 151 controls each component of the deposition apparatus 100. To the process controller 151, a user interface 152 and a storage 153 are connected.

The user interface 152 includes an input unit including a touch panel display or a keyboard for performing an input operation of a command for the operator to manage the deposition apparatus 100, and a display unit including a display for visualizing and displaying the operation status of the deposition apparatus 100.

The storage 153 stores a so-called process recipe including a control program for implementing various processes executed by the deposition apparatus 100 under the control of the process controller 151 and a program for executing the processes according to the processing conditions in each component of the deposition apparatus 100. The process recipe is stored in a storage medium in the storage 153. The storage medium may be a hard disk, a semiconductor memory, or a portable one such as a CD-ROM, a DVD, a flash memory, or the like. The process recipe may also be suitably transmitted from other devices, for example, via a dedicated line.

The process recipe is read from the storage 153 according to an operator's instruction or the like from the user interface 152 as necessary, and the process controller 151 causes the deposition apparatus 100 to perform processing according to the read process recipe.

### <Deposition Method>

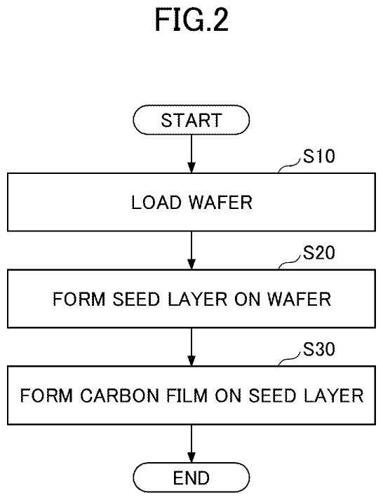

Referring to FIGS. 2 to 4, a deposition method for the carbon film according to an embodiment performed by the deposition apparatus 100 of FIG. 1 will be described.

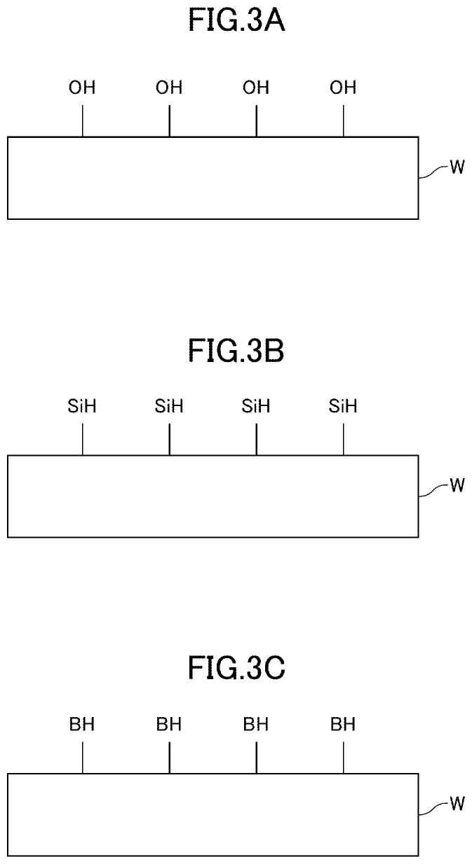

First, by inserting the boat 112 in which a plurality of (for example, 50 to 150) substrates W is mounted into the processing chamber S of the deposition apparatus 100 from the bottom, the substrates W are loaded into the processing chamber S (step S10). The substrate W has, for example, an O—H terminated surface (see FIG. 3A). Then, by closing the lower opening of the manifold 110 with the lid 116, the inside of the processing chamber S is made into a sealed space. Then, the inside of the processing chamber S, which is a sealed space, is evacuated to maintain a predetermined reduced-pressure atmosphere, and by controlling the power supplied to the heater 108, the temperature of the substrate W is raised and maintained at the process temperature, and the boat 112 is kept rotating.

Next, the seed layer is formed on the substrate W in order to increase the adhesion between the substrate W and the carbon film (step S20). Step S20 is performed with the substrate W maintained at a temperature of, for example, 200° C. or more and 300° C. or less, preferably 215° C. In step S20, the seed layer having a film thickness of, for example, 0.4 nm or less, and preferably 0.1 nm, is formed.

In step S20, first, DIPAS is supplied as the first seed gas from the first seed gas source 131e to form a Si—H bond as the first seed layer on the surface of the substrate W (see FIG. 3A). Because the Si—H bond is formed on the surface of the substrate W, the B—H bond is easily formed on the surface of the substrate W when the second seed gas is supplied to the substrate W.

Then, the supply of DIPAS is stopped and B₂H₆ gas is supplied as the second seed gas from the second seed gas source 131f to form a B—H bond as the second seed layer on the surface of the substrate W on which the Si—H bond is formed (see FIG. 3C). Because the step of forming the B—H bond is performed with the Si—H bond formed on the surface of the substrate W, the formation of the B—H bond is initiated in a short time. That is, the incubation time is greatly reduced.

Next, the supply of B₂H₆ gas is stopped, and a carbon film is deposited on the seed layer by thermal CVD without plasma assist (step S30). Step S30 is performed under the same temperature environment as step S20, or a temperature environment higher than step S20. For example, step S30 is performed after step S20 and after increasing the temperature of the substrate W to, for example, 350° C. or more and 450° C. or less, preferably 390° C.

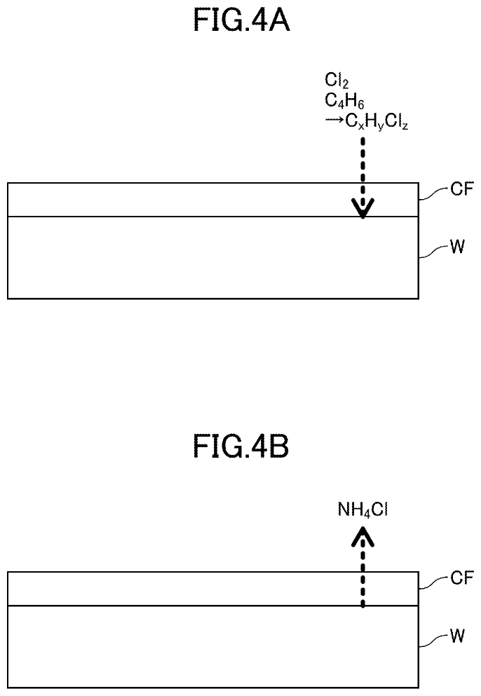

In step S30, first, C₄H₆ gas is supplied as the carbon-containing gas from the carbon-containing gas source 131a, and Cl₂ gas is supplied as the thermal decomposition temperature drop gas from the thermal decomposition temperature drop gas source 131b. C₄H₆ reacts with Cl₂ to give CₓH_{y}Cl_{z} (where x, y, and z are natural numbers of 1 or more), thus lowering the thermal decomposition temperature. Accordingly, the C₄H₆ gas is heated to a predetermined temperature lower than the thermal decomposition temperature to be thermally decomposed, and a carbon film CF is deposited on the seed layer by thermal CVD (see FIG. 4A). As described above, when the carbon film CF is deposited, by using the thermal decomposition temperature drop gas, the thermal decomposition temperature of the carbon-containing gas is lowered by the catalytic effect, and the carbon film is deposited at a temperature lower than the thermal decomposition temperature of the carbon-containing gas. That is, the temperature of 650° C. or more, which was conventionally required for depositing the carbon film in the thermal CVD process using the carbon-containing gas, can be lowered to the lower temperature, enabling deposition at a low temperature of about 300° C.

Then, the supply of the C₄H₆ gas and the Cl₂ gas is stopped, and NH₃ gas is supplied as the halogen reactive gas from the halogen reactive gas source 131c to reduce the halogen contained in the carbon film CF (see FIG. 4B). The NH₃ gas reacts with the Cl terminal to form NH₄Cl, thereby removing the Cl terminal. Thus, the NH₃ gas is supplied as a reactive gas for removing Cl. Because the NH₃ gas is also capable of reacting with F, Br, and I, which are halogens other than Cl, the NH₃ gas can be used as the halogen reactive gas when halogen gases other than Cl are used. The step of reducing the halogen is preferably performed under a higher pressure environment than the step of depositing the carbon film CF. Accordingly, the nitriding power of the NH₃ gas is enhanced and the removal effect of the halogen is improved. The step of reducing the halogen is performed with the pressure in the processing chamber S maintained at, for example, 1200 Pa or more and 16000 Pa or less (9 Torr or more and 120 Torr or less).

In step S30, by repeating a cycle including the step of depositing the carbon film CF and the step of reducing the halogen, the carbon film CF having a desired thickness is deposited.

Before and after supplying the NH₃ gas, an exhaust step and/or a purge step may be performed. The exhaust step and/or the purge step are performed to remove the C₄H₆ gas, the Cl₂ gas, the NH₃ gas, and the like present in the processing chamber S. The exhaust step is a step of increasing the exhaust volume by increasing the opening of the exhaust valve. The purge step is a step of supplying an inert gas to the substrate W. Either one of the exhaust step or the purge step may be performed, or both may be performed. Optionally, the exhaust step and the purge step may be omitted. Examples of the inert gas include N₂ gas, Ar gas, and He gas.

After the deposition of the carbon film CF is completed, the inside of the processing chamber S is exhausted by the exhaust device 107, and the inside of the processing chamber S is purged by supplying, for example, N₂ gas as a purge gas from the inert gas source 131d into the processing chamber S. Subsequently, after returning the inside of the processing chamber S to the atmospheric pressure, the boat 112 is lowered to unload the substrate W.

### EXAMPLE

### (Underlayer Damage and Adhesion)

A carbon film was formed after a first seed layer and a second seed layer were formed on an underlayer by the deposition method for the carbon film according to the embodiment described above. Then, the underlayer damage and the adhesion between the underlayer and the carbon film were evaluated. For comparison, the underlayer damage and the adhesion between the underlayer and the carbon film were evaluated when the carbon film was formed without forming the first seed layer and the second seed layer on the underlayer.

In Example 1, using silicon (Si) as the underlayer, the carbon film was deposited after the first seed layer and the second seed layer were formed on the silicon, by the deposition method for the carbon film according to the embodiment. In Example 1, DIPAS was used as the first seed gas, B₂H₆ was used as the second seed gas, C₄H₆ was used as the carbon-containing gas, Cl₂ was used as the thermal decomposition temperature drop gas, and NH₃ was used as the halogen reactive gas. In Example 1, the underlayer was heated to 215° C. to form the first seed layer and the second seed layer, and the underlayer was heated to 390° C. to form the carbon film.

In Example 2, using a silicon oxide film (SiO₂) as the underlayer, the carbon film was deposited after the first seed layer and the second seed layer were formed on the silicon oxide film under the same conditions as Example 1.

In Comparative Example 1, using silicon as the underlayer, the carbon film was deposited under the same conditions as Example 1 without forming the first seed layer and the second seed layer on the silicon.

In Comparative Example 2, using the silicon oxide film as the underlayer, the carbon film was deposited under the same conditions as Example 1 without forming the first seed layer and the second seed layer on the silicon oxide film.

In Comparative Example 3, using silicon as the underlayer, the carbon film was deposited without forming the first seed layer and the second seed layer on the silicon. In Comparative Example 3, the underlayer was heated to 700° C., which is higher than 390° C., without using the thermal decomposition temperature drop gas, and the carbon film was deposited.

In Comparative Example 4, using the silicon oxide film as the underlayer, the carbon film was deposited under the same conditions as Comparative Example 3 without forming the first seed layer and the second seed layer on the silicon oxide film.

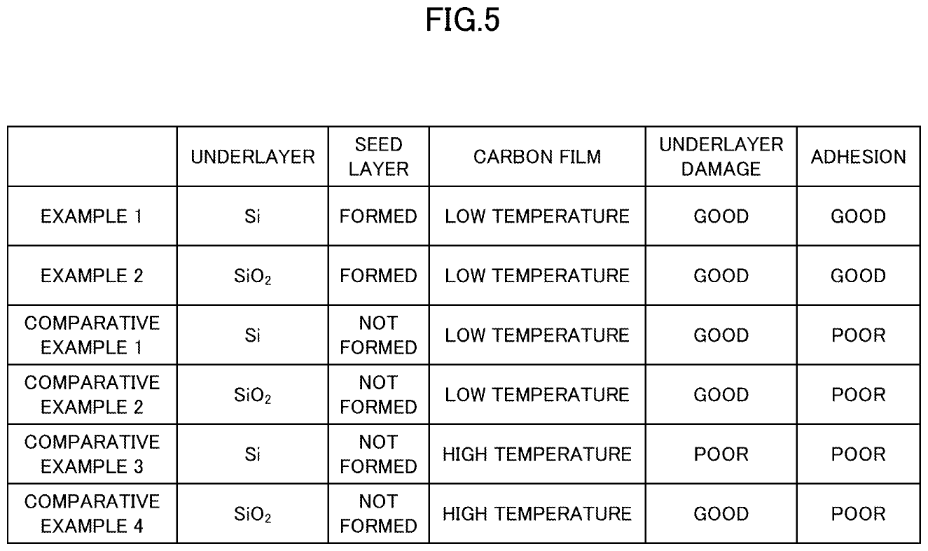

FIG. 5 is a diagram illustrating the evaluation results of the underlayer damage and the adhesion, and illustrates the results of performing Examples 1 to 2 and Comparative Examples 1 to 2. In FIG. 5, the “underlayer” section indicates the type of the underlayer and indicates whether the underlayer is silicon (Si) or silicon oxide (SiO₂). The “seed layer” section indicates whether the seed layer is formed on the underlayer. The “carbon film” section indicates the deposition condition of the carbon film, the “low temperature” indicates that the carbon film was deposited at a low temperature (390° C.) using the thermal decomposition temperature drop gas, and the “high temperature” indicates that the carbon film was deposited at 700° C. without using the thermal decomposition temperature drop gas. The “underlayer damage” section indicates the observed presence or absence of the underlayer damage using a scanning electron microscope (SEM), after the carbon film is formed on the underlayer. In the “underlayer damage” section, “good” indicates that no underlayer damage was observed and “poor” indicates that underlayer damage was observed. The “adhesion” section indicates the observed presence or absence of peeling of the carbon film by the adhesion test, after the carbon film is formed on the underlayer. In the “adhesion” section, “good” indicates that no peeling of the carbon film was observed, and “poor” indicates that peeling of the carbon film was observed.

As illustrated in FIG. 5, in both Example 1 and Example 2, the underlayer damage was not observed, and the peeling of the carbon film was not observed. These results indicate that according to the deposition method for the carbon film according to the embodiment, the carbon film without underlayer damage and with excellent adhesion can be formed, regardless of the type of the underlayer.

In contrast, in both Comparative Example 1 and Comparative Example 2, the underlayer damage was not observed, but the peeling of the carbon film was observed. These results indicate that when the carbon film is deposited without forming the first seed layer and the second seed layer on the underlayer, the adhesion between the underlayer and the carbon film is low.

In Comparative Example 3, the underlayer damage was observed, and the peeling of the carbon film was observed. In Comparative Example 4, the underlayer damage was not observed, but the peeling of the carbon film was observed. These results indicate that when the carbon film is deposited without forming the first seed layer and the second seed layer on the underlayer and without using the thermal decomposition temperature drop gas, the adhesion between the underlayer and the carbon film is low, and the underlayer damage occurs depending on the type of the underlayer.

(XPS spectrum)

A carbon film was formed after a first seed layer and a second seed layer were formed on an underlayer by the deposition method for the carbon film according to the embodiment described above. Then, the XPS spectrum was measured by X-ray photoelectron spectroscopy (XPS) (Example 3). For comparison, a BN film with a thickness of 2.5 nm was formed as a seed layer on the underlayer, and then a carbon film was formed, and the XPS spectrum was measured by the XPS (Comparative Example 5).

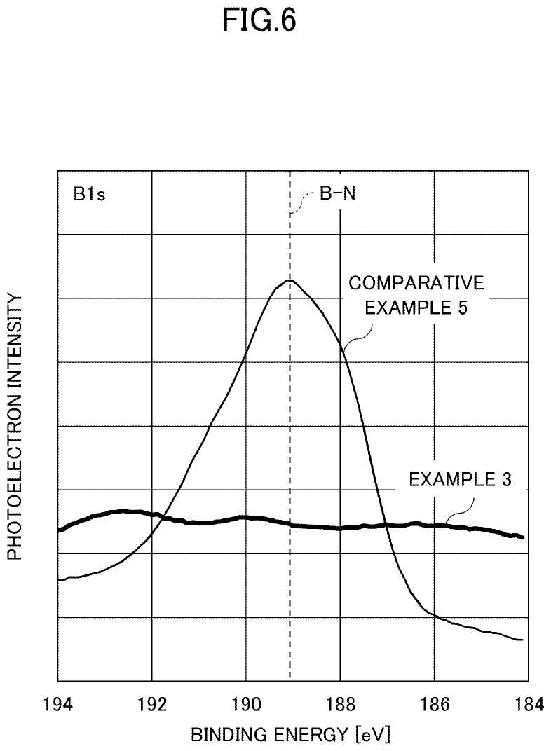

FIG. 6 is a diagram illustrating the measurement results of the XPS spectrum of the carbon film. In FIG. 6, the horizontal axis represents the binding energy [eV] and the vertical axis represents the photoelectron intensity. As illustrated in FIG. 6, in the carbon film of Example 3, it can be seen that the peak derived from the B1s orbital does not appear. In contrast, in the carbon film of Comparative Example 5, the peak derived from the B1s orbital appears at the position of the binding energy of 189 eV (B—N bond). From these results, it can be said that the BN film is not formed, or not appreciably formed, on the carbon film of Example 3.

The embodiments disclosed herein should be considered to be exemplary in all respects and not limiting. The above embodiments may be omitted, substituted, or modified in various forms without departing from the appended claims and spirit thereof.

In the above embodiments, the deposition apparatus has been described as a batch-type device that performs processes on multiple substrates simultaneously, but the present disclosure is not limited thereto. For example, the deposition apparatus may be a single-wafer type apparatus that processes substrates one at a time.

According to the present disclosure, it is possible to form a carbon film that can suppress underlayer damage and exhibits excellent adhesion.

What is claimed is:

1. A deposition method comprising:
forming a seed layer on a substrate; and
forming a carbon film on the seed layer,
wherein the forming the seed layer includes:
supplying an aminosilane-based gas to the substrate to form a Si—H bond on a surface of the substrate; and
supplying a boron-containing gas to the substrate to form a B—H bond on the surface on which the Si—H bond is formed.

2. The deposition method according to claim 1, wherein the forming the carbon film includes supplying a carbon-containing gas and a halogen gas to the substrate to form the carbon film on the seed layer.

3. The deposition method according to claim 2, wherein the forming the carbon film includes supplying a gas that reacts with a halogen and reducing a halogen amount in the carbon film.

4. The deposition method according to claim 3, wherein the forming the carbon film includes repeating a cycle including forming the carbon film and reducing the halogen amount a plurality of times.

5. The deposition method according to claim 4, wherein the reducing the halogen amount is performed under a higher pressure environment compared to the forming the carbon film.

6. The deposition method according to claim 5, wherein the forming the carbon film is performed under a same temperature environment as in the forming the seed layer or under a higher temperature environment compared to the forming the seed layer.

7. The deposition method according to claim 6, wherein the forming the seed layer and the forming the carbon film are performed in a same processing chamber.

8. The deposition method according to claim 3, wherein the reducing the halogen amount is performed under a higher pressure environment compared to the forming the carbon film.

9. The deposition method according to claim 8, wherein the forming the carbon film is performed under a same temperature environment as in the forming the seed layer or under a higher temperature environment compared to the forming the seed layer.

10. The deposition method according to claim 9, wherein the forming the seed layer and the forming the carbon film are performed in a same processing chamber.

11. The deposition method according to claim 1, wherein the forming the carbon film is performed under a same temperature environment as in the forming the seed layer or under a higher temperature environment compared to the forming the seed layer.

12. The deposition method according to claim 1, wherein the forming the seed layer and the forming the carbon film are performed in a same processing chamber.

13. A deposition apparatus comprising:
a processing chamber configured to accommodate a substrate;
a gas supply configured to supply a process gas into the processing chamber; and
a controller configured to control the gas supply,
wherein the controller is configured to execute:
forming a seed layer on a substrate; and
forming a carbon film on the seed layer,
wherein the forming the seed layer includes:
supplying an aminosilane-based gas to the substrate to form a Si—H bond on a surface of the substrate; and
supplying a boron-containing gas to the substrate to form a B—H bond on the surface on which the Si—H bond is formed.
